(19) United States
(12) Patent Application Publication
(10) Pub. No.: US 2008/0069380 A1
(43) Pub. Date: Mar. 20, 2008

(54) Device for dynamically adjusting volume within communication apparatus

(75) Inventor: Chieh-Yuan Cheng, Taipei (TW)

Correspondence Address: REED SMITH LLP, Suite 1400, 3110 Fairview Park Drive, Falls Church, VA, 22042, US

(73) Assignee: Compal Communications, Inc.

(21) Appl. No.: 11/898,998

(22) Filed: Sep. 18, 2007

(30) Foreign Application Priority Data
Sep. 19, 2006 (TW) 095216689

(51) Int. Cl. H03G 3/20

(52) U.S. Cl. 381/107

(57) ABSTRACT

The invention relates to a device for dynamically adjusting volume within communication apparatus. The communication apparatus includes a speaker and an amplifier electrically connected to the speaker. The device is configured in the communication apparatus and includes a distance sensing unit and a signal processing circuit. The distance sensing unit is used for sensing a distance between the communication apparatus and a user to obtain a distance data. The signal processing circuit is used for dynamically adjusting a gain of the amplifier according to the distance data. The amplifier amplifies an input signal by the gain and then outputs an output signal to the speaker. Therefore, the output volume of the communication apparatus can be dynamically adjusted instead of being manually adjusted.

### BACKGROUND OF THE INVENTION

1. Field of the Invention

The invention relates to a device for dynamically adjusting volume, and more particularly to a device for dynamically adjusting volume within a communication apparatus.

2. Description of the Prior Art

When a user utilizes a general communication apparatus, such as a cell phone for communication, the communication apparatus can be switched to either a general talk mode or a speaker mode. And, when the general talk mode is chosen, the cell phone needs to be placed close to an ear of the user. As a result, the temperature of where the ear is close to on the cell phone is risen and makes the user feel uncomfortable. Therefore, the user needs to maintain a certain distance from the ear to the cell phone to ease the uncomfortable feeling. On the other hand, when the speaker mode is chosen, the cell phone does not need to be close to an ear of the user. However, the user usually needs to adjust the output volume of the cell phone, even switch back to the general talk mode, depending on where the user talks and what the user talks about. In short, no matter which mode is chosen, the user has to manually adjust the output volume of the cell phone. Namely, the output volume can not be dynamically adjusted according to the distance between the user and the communication apparatus; it is very inconvenient for users.

### SUMMARY OF THE INVENTION

The scope of the invention is to provide a device for dynamically adjusting volume within a communication apparatus.

The device of the invention is used for dynamically adjusting the output volume of the communication apparatus. The communication apparatus further comprises a speaker, an amplifier, and a microphone. The device is configured in the communication apparatus and comprises a distance sensing unit and a signal processing circuit. The distance sensing unit is used for sensing a distance between the communication apparatus and the user to obtain a distance data. The signal processing circuit is electrically connected to the distance sensing unit and the amplifier. The amplifier amplifies an input signal by a gain of the amplifier and then outputs an output signal to the speaker.

Another scope of the invention is to provide a device comprising an analog to digital converter (AD converter) and a signal processing circuit. The device is used for dynamically adjusting volume within a communication apparatus. The communication apparatus comprises a speaker, an amplifier, and a microphone. The AD converter is electrically connected to the microphone and is used for digitalizing a voice signal inputted from the microphone. The signal processing circuit is electrically connected to the AD converter and the amplifier. According to the digitalized voice signal inputted from the AD converter, the signal processing circuit generates a control signal for setting a gain of the amplifier. The amplifier amplifies an input signal by the gain and then outputs an output signal to the speaker.

The advantage and spirit of the invention may be understood by the following recitations together with the appended drawings.

### BRIEF DESCRIPTION OF THE APPENDED DRAWINGS

FIG. 1 is a functional block diagram illustrating a communication apparatus according to a first preferred embodiment of the invention.

FIG. 2 is a functional block diagram illustrating a communication apparatus according to a second preferred embodiment of the invention.

FIG. 3 is a functional block diagram illustrating a communication apparatus according to a third preferred embodiment of the invention.

### DETAILED DESCRIPTION OF THE INVENTION

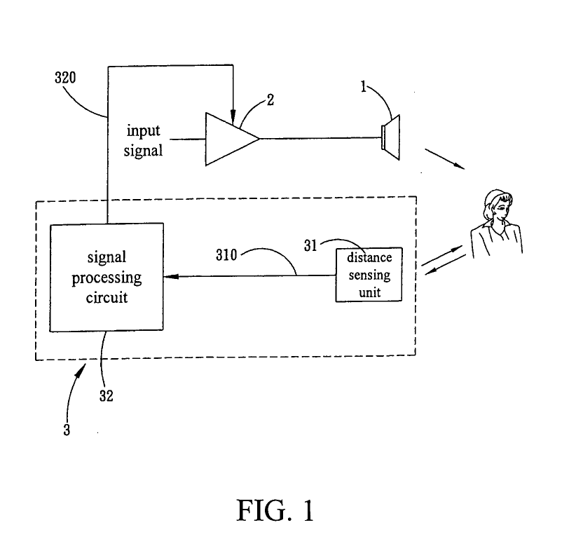

Please refer to FIG. 1. FIG. 1 is a functional block diagram illustrating a communication apparatus according to a first preferred embodiment of the invention. The device 3 is used for dynamically adjusting output volume within the communication apparatus. As shown in FIG. 1, the communication apparatus further comprises a speaker 1 and an amplifier 2 electrically connected to the speaker 1. The amplifier 2 amplifies an input signal by a gain of the amplifier 2 and then outputs an output signal to the speaker 1.

The device 3 is configured in the communication apparatus. The device 3 comprises a distance sensing unit 31 and a signal processing circuit 32. The distance sensing unit 31 is used for sensing a distance between the communication apparatus and a user to obtain a distance data 310. The signal processing circuit 32 is electrically connected to the distance sensing unit 31 and the amplifier 2. According to the distance data 310, the signal processing circuit 32 generates a control signal 320 for setting the gain of the amplifier 2. Accordingly, the amplifier 2 amplifies an input signal by the gain and then outputs an output signal to the speaker 1.

In this embodiment, the communication apparatus is, but not limit to, a cell phone, and the distance sensing unit 31 is, but not limit to, an infrared distance sensor. In fact, the communication apparatus can be a walkie-talkie or a local phone, and the distance sensing unit can be a supersonic distance sensor, a laser distance sensor, or a complementary metal oxide semiconductor (CMOS) image sensor. The infrared distance sensor, the supersonic distance sensor, or the laser distance sensor respectively transmits a signal such as an infrared ray, a supersonic wave, or a laser light to a target, and receives a reflecting signal from the target. According to the time difference between the transmitting and receiving, a distance data of the target is determined. The CMOS image sensor captures an image of the target, and then the image is processed and analyzed to obtain a distance data of the target. Additionally, the CMOS sensor can be configured with an infrared ray generator (ex: light emitting diode (LED)). An infrared ray is transmitted by the infrared generator, and the reflecting signal from the target is then received by the CMOS image sensor. Finally, the distance data of the target is obtained.

In this embodiment, the signal processing circuit 32 digitalizes a distance data 310 sensed by the distance sensing unit 31, and then the digitalized distance data are transformed into a corresponding gain value by the digital signal processor. According to the corresponding gain value, the signal processing circuit 32 outputs a control signal 320 for setting the gain of the amplifier. The digital signal processor establishes the relation between the digitalized distance data and the gain, and a higher gain corresponds to a farther distance.

When a user communicates with others by the communication apparatus in FIG. 1, the signal processing circuit 32 digitalizes a distance data outputted from the distance sensing unit 31 and then transforms the digitalized distance data into a gain value according to the corresponding relation. The signal processing circuit 32 outputs a control signal 320 for setting the gain of the amplifier 2, and the amplifier 2 amplifies an input signal by the gain and then outputs an output signal to the speaker 1. When the distance between the communication apparatus and the user is farther, the corresponding gain is higher. The signal processing circuit 32 adjusts the gain of the amplifier 2 to be higher, such that the communication apparatus volumes up. On the contrary, when the communication apparatus is closer to the user, the corresponding gain is lower. The signal processing circuit 32 adjusts the gain of the amplifier 2 to be lower, such that the communication apparatus volumes down.

In the period of communication, when the distance between the communication apparatus and the user is varied, the output volume of the communication apparatus can be dynamically adjusted instead of being manually adjusted.

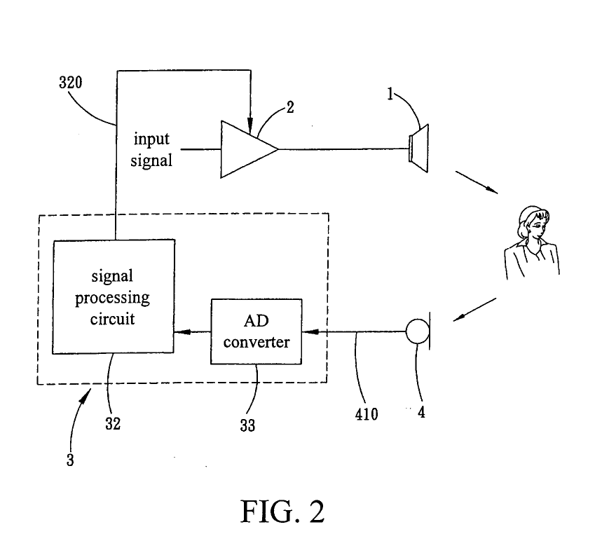

Please refer to FIG. 2. FIG. 2 is a functional block diagram illustrating a communication apparatus according to a second preferred embodiment of the invention. The difference between the first embodiment shown in the FIG. 1 and the second embodiment shown in the FIG. 2 is that the signal processing circuit 32 in FIG. 2 dynamically adjusts a gain of the amplifier 2 according to a talking volume of a user instead of the distance data 310 sensed by the distance sensing unit 31. The talking volume of the user can represent a distance between the communication apparatus and the user. In this embodiment, an analog to digital converter (AD converter) 33 is electrically connected to a microphone 4 of the cell phone. The AD converter 33 is used for digitalizing a voice signal inputted from the microphone 4, and then outputs the digitalized voice signal to the signal processing circuit 32. The signal processing circuit processes and analyses the digitalized voice signal to obtain the talking volume of the user. Afterward, the signal processing circuit 32 generates a control signal 320 for setting the gain of the amplifier 2 according to the talking volume of the user.

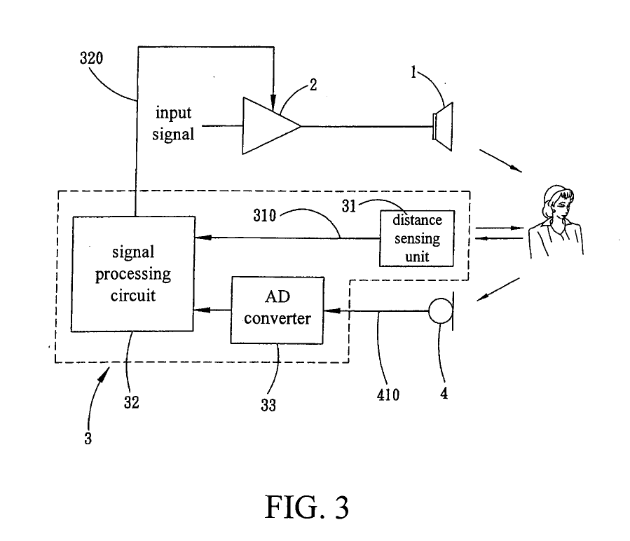

Please refer to FIG. 3. FIG. 3 is a functional block diagram illustrating a communication apparatus according to a third preferred embodiment of the invention. The third embodiment of the invention combines the first and second embodiments. Alternatively, the signal processing circuit 32 is electrically connected to the distance sensing unit 31 and the AD converter 33. The AD converter 33 is used for digitalizing the voice signal 410 inputted from the microphone 4. The signal processing circuit 32 is used for dynamically adjusting the gain of the amplifier 2 according to the distance data and the talking volume, such that the output volume can be adjusted immediately according to different kinds of situations.

Based upon the distance between the user and the communication apparatus sensed by the distance sensing unit 31 or the talking volume of the user, the gain of the amplifier 2 is adjusted by the signal processing circuit 32, such that the output volume can be dynamically adjusted by the device 3 within the communication apparatus of the invention.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A device for dynamically adjusting volume within a communication apparatus the device being adapted to adjust output volume of the communication apparatus, the communication apparatus comprising a speaker, an amplifier, and a microphone, the device being configured in the communication apparatus and comprising:
a distance sensing unit, for sensing a distance between the communication apparatus and a user to obtain a distance data; and
a signal processing circuit, electrically connected to the distance sensing unit and the amplifier, according to the distance data, the signal processing circuit generating a control signal for adjusting a gain of the amplifier, the amplifier adjusting an input signal by the gain and then outputting an output signal to the speaker.

2. The device of claim 1, wherein the distance sensing unit is an infrared distance sensor.

3. The device of claim 1, wherein the distance sensing unit is a supersonic distance sensor.

4. The device of claim 1, wherein the distance sensing unit is a laser distance sensor.

5. The device of claim 1, wherein the distance sensing unit is a complementary metal oxide semiconductor (CMOS) image sensor.

6. The device of claim 1, wherein the signal processing circuit further receives a voice signal inputted from the microphone and adjusts the gain according to intensity of the voice signal.

7. The device of claim 6, further comprising an analog to digital converter (AD converter) for digitalizing the voice signal inputted from the microphone and outputting the digitalized voice signal to the signal processing circuit, and according to the volume of the voice signal, the signal processing circuit generating a control signal for adjusting the gain of the amplifier.

8. A device for dynamically adjusting volume within a communication apparatus, the device being adapted to adjust output volume of the communication apparatus, the communication apparatus comprising a speaker, an amplifier, and a microphone, the device being configured in the communication apparatus and comprising:
an analog to digital converter (AD converter), electrically connected to the microphone, for digitalizing a voice signal inputted from the microphone; and
a signal processing circuit, electrically connected to the AD converter and the amplifier, according to the digitalized voice signal inputted from the AD converter, the signal processing circuit generating a control signal for adjusting a gain of the amplifier, the amplifier adjusting an input signal by the gain and then outputting an output signal to the speaker.

9. The device of claim 8, wherein according to the volume of the voice signal, the signal processing circuit generates a control signal for adjusting the gain of the amplifier.
